(19) United States
(12) Patent Application Publication
(10) Pub. No.: US 2026/0344416 A1
(43) Pub. Date: Oct. 29, 2026

(54) SEMICONDUCTOR STRUCTURE AND METHOD OF MANUFACTURING SAME

(71) Applicant: Taiwan Semiconductor Manufacturing Company, Ltd., Hsin-Chu (TW)

(72) Inventors: Ching-Chung Hsu, Taichung City (TW); Chung-Long Chang, Hsinchu City (TW); Chien-Hsien Kuo, Tainan City (TW)

(21) Appl. No.: 19/349,020

(22) Filed: Oct. 3, 2025

Related U.S. Application Data
(60) Provisional application No. 63/793,053, filed on Apr. 23, 2025.

(51) Int. Cl. H10W 20/40

(52) U.S. Cl. CPC H10W 20/497

(57) ABSTRACT

A semiconductor structure includes a first magnetic layer, a first dielectric layer over the first magnetic layer, conductive features over the first dielectric layer, a second dielectric layer over the conductive features, and a second magnetic layer over the second dielectric layer. The conductive features are embedded in the second dielectric layer. In a top view, the first magnetic layer extends beyond a boundary of the second magnetic layer.

### PRIORITY DATA

The present application claims the benefit of U.S. Provisional Application No. 63/793,053, filed Apr. 23, 2025, the entirety of which is herein incorporated by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, for inductors, electro-magnetic interference (EMI) effect and inductance become more challenging in the scaling down process. Although existing structures and methods have been generally adequate for their intended purposes, they are not entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for fabricating a semiconductor structure according to various aspects of the present disclosure.

FIGS. 2, 3, 4, 5, 6, 7, 8, and 9 illustrate fragmentary cross-sectional views of an exemplary structure at various fabrication stages associated with the method of FIG. 1 according to various aspects of the present disclosure.

FIG. 10 illustrates a fragmentary top view of an exemplary structure at various fabrication stages associated with the method of FIG. 1 according to various aspects of the present disclosure.

FIG. 11 illustrates a diagram of magnetic field in and around an exemplary structure fabricated by the method of FIG. 1 according to various aspects of the present disclosure.

FIGS. 12, 13, and 14 illustrate fragmentary schematic cross-sectional views of exemplary structures fabricated by the method of FIG. 1 according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/–10% of the number described, based on known manufacturing tolerances associated with manufacturing a feature having a characteristic associated with the number. For example, a material layer having a thickness of “about 5nm” can encompass a dimension range from 4.25nm to 5.75nm where manufacturing tolerances associated with depositing the material layer are known to be +/–15% by one of ordinary skill in the art. Other ranges are possible as known by those skilled in the art and may be process dependent.

Inductors or inductive structures can be used in various electronic applications, such as radio frequency filters, alternating current (AC) blockers, voltage regulators, transformers, and/or the like. An inductive structure may include magnetic elements, such as magnetic layers or films. An inductive structure may be formed over one or more passivation layers and other layers and devices. Electro-magnetic interference (EMI) effect between the underlying features and the inductive structure may induce inductance drop and/or resistance increase, and may impact overall performance of the semiconductor structure. While existing techniques are generally adequate for their intended purposes, they are not satisfactory in all aspects.

The present disclosure is generally related to semiconductor structures and methods of fabricating same. More specifically, the present disclosure is related to semiconductor structures including inductors. In some embodiments, the semiconductor structure includes a substrate, a circuitry structure over the substrate, a passivation layer over the circuitry structure, and an inductor over the passivation layer. In some embodiments, the inductor includes a first magnetic layer, conductive lines over the first magnetic layer, a second magnetic layer over and around the conductive lines, and isolation layers isolating the first magnetic layer, the second magnetic layer, and the conductive lines. In the present disclosure, the first magnetic layer is wider than the second magnetic layer, such that the first magnetic layer laterally extends beyond outer sidewalls of the second magnetic layer. Benefits may include that electro-magnetic interference (EMI) effect between the inductor and the circuitry structure is reduced, inductance of the inductor is increased, and resistance of the inductor is reduced.

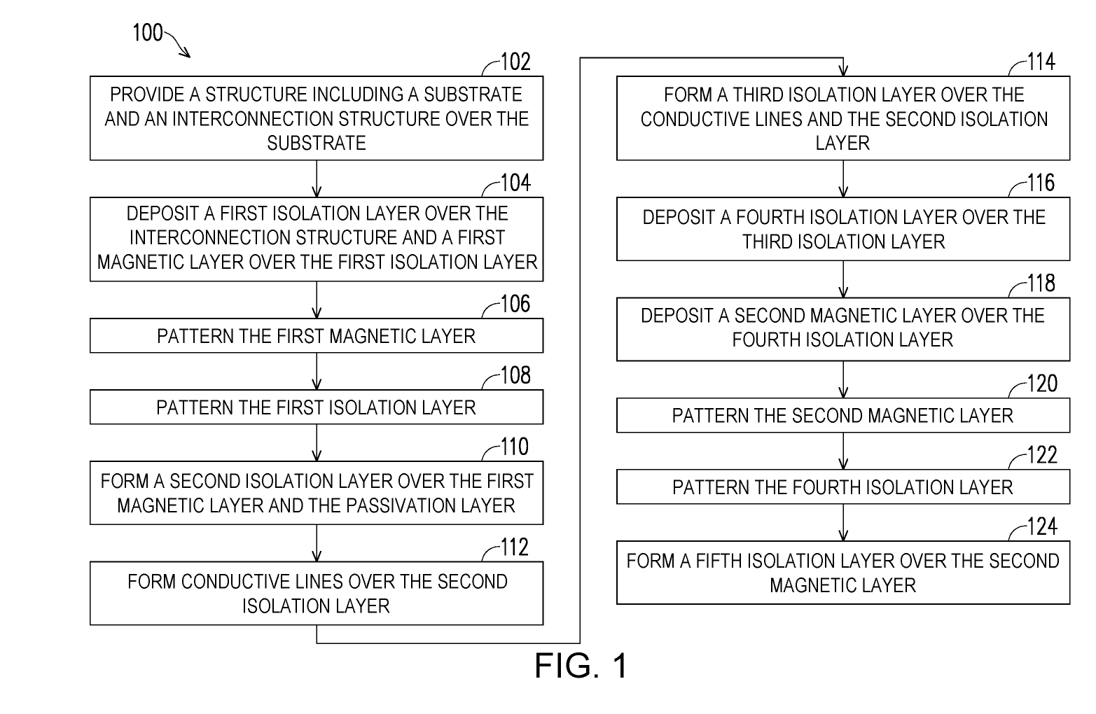

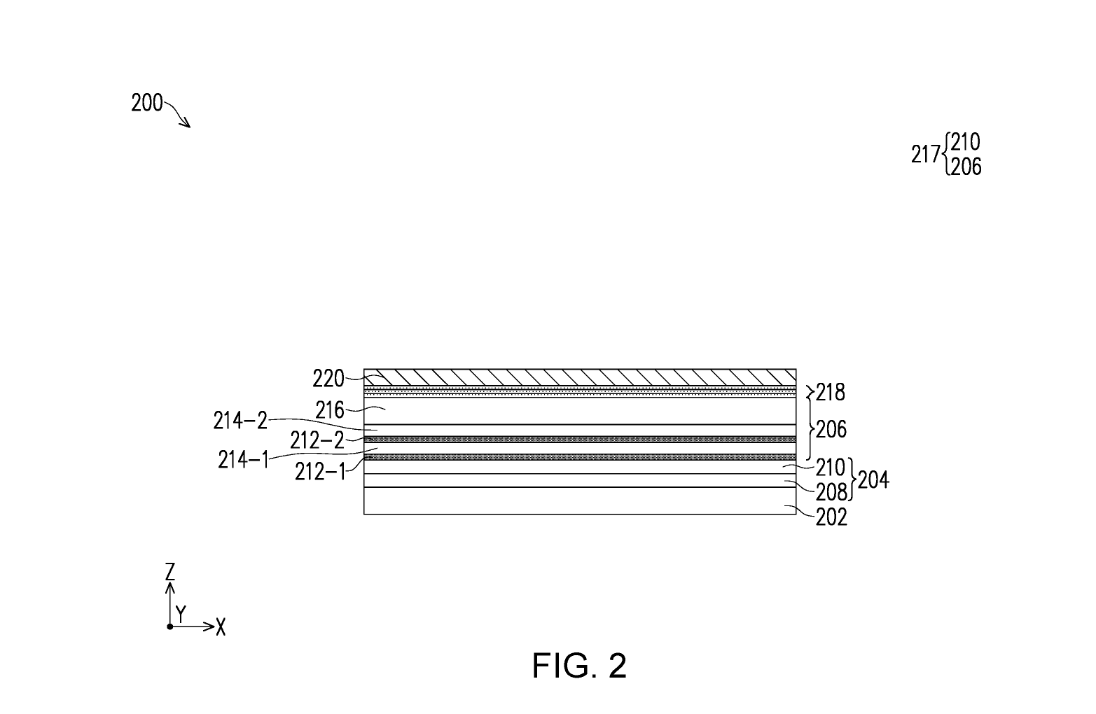

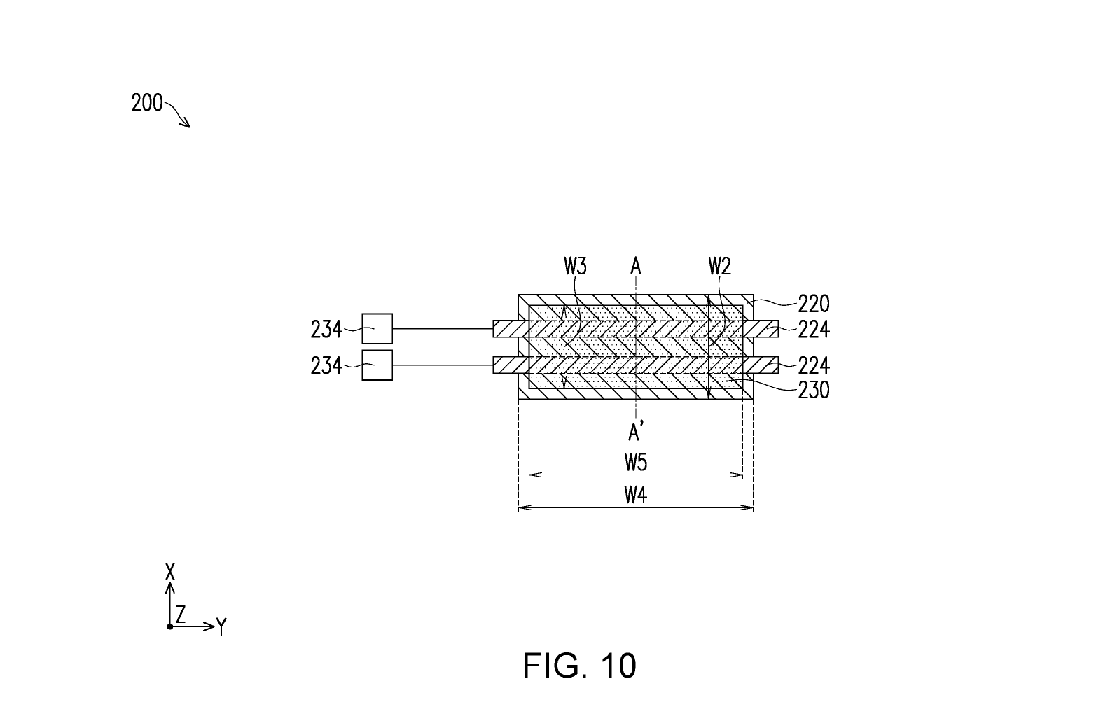

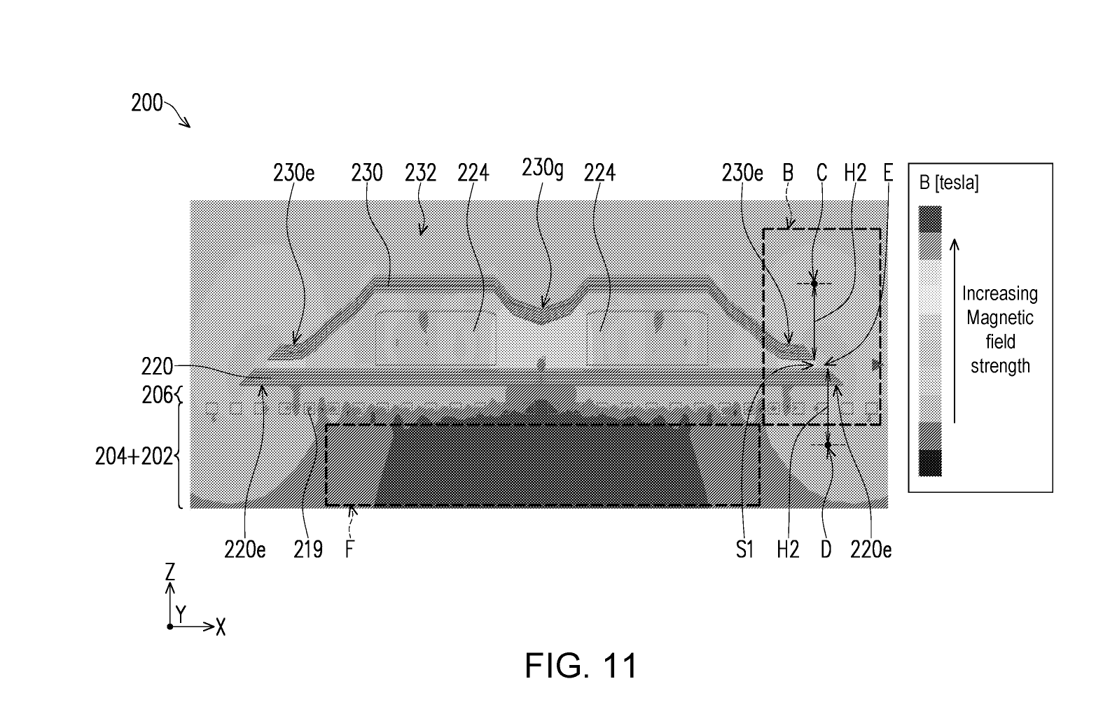

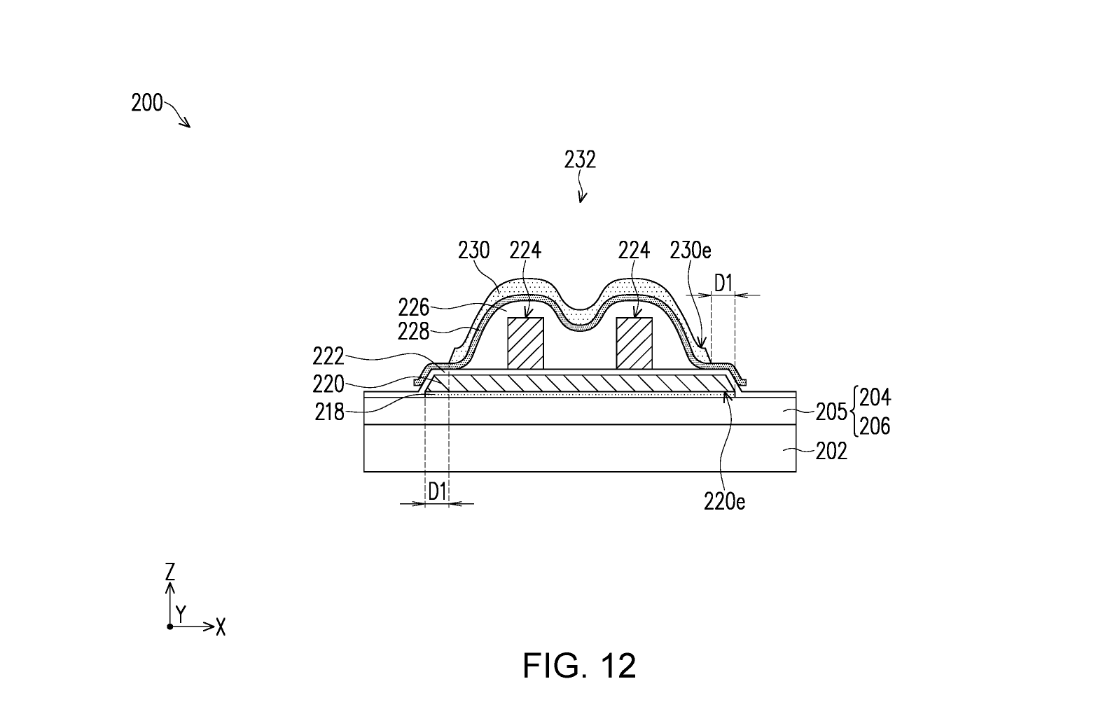

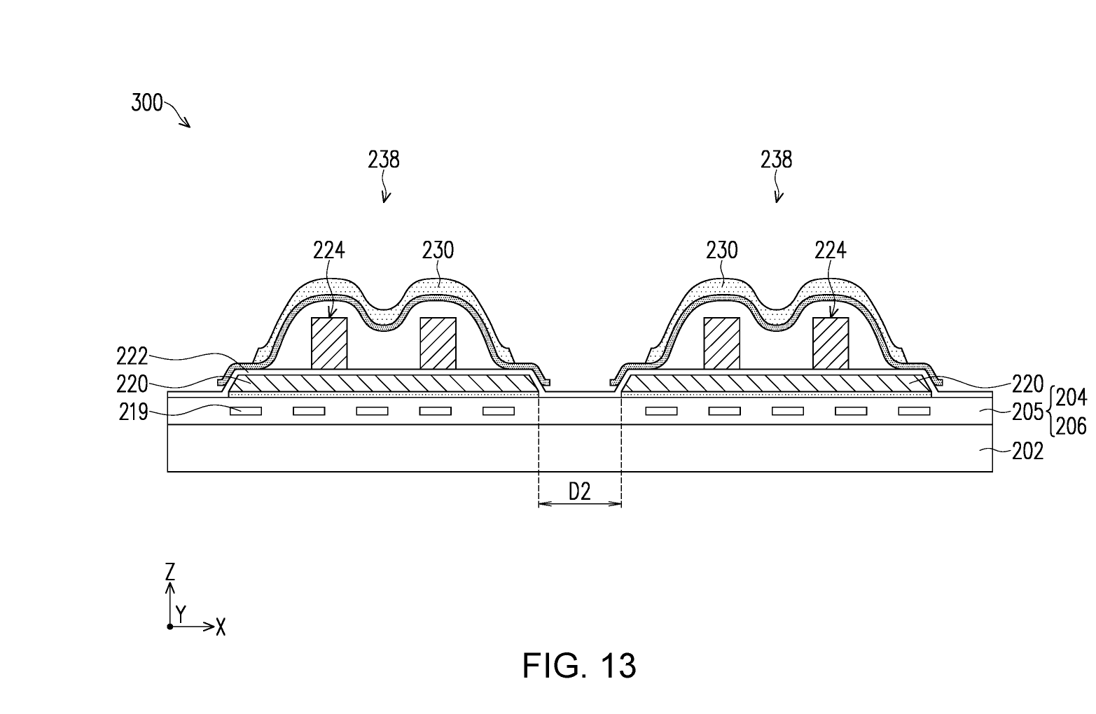

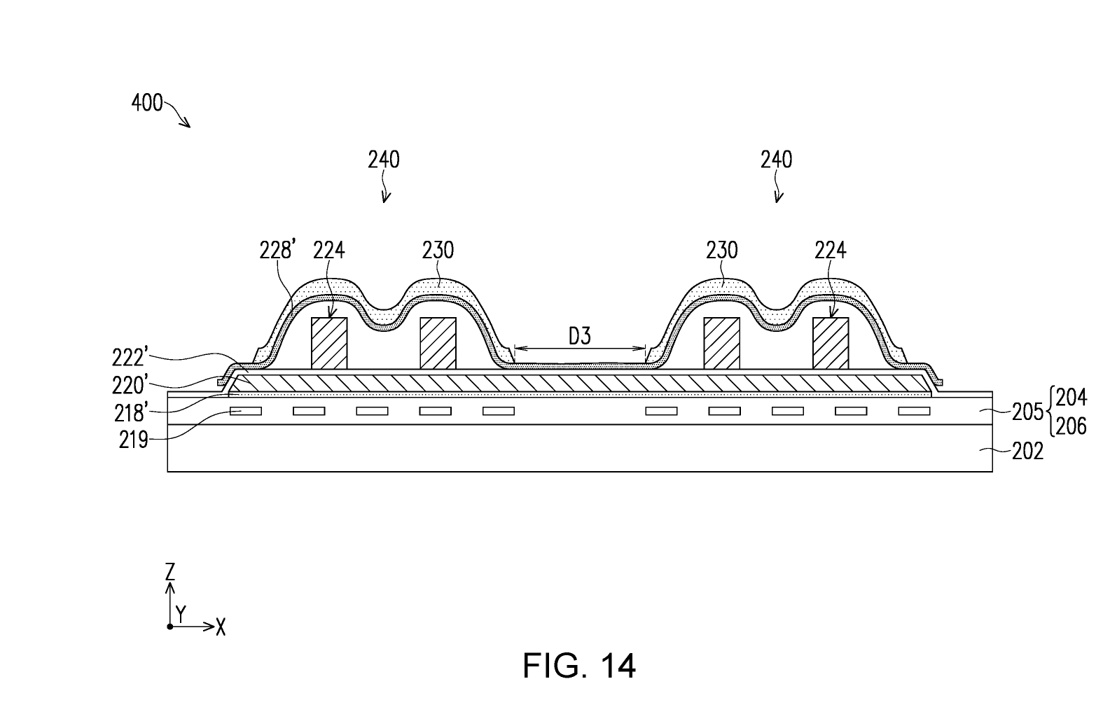

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-10. FIGS. 2-9 are fragmentary cross-sectional views of a structure 200 at different stages of fabrication according to embodiments of method 100 in FIG. 1. FIG. 10 is a fragmentary top view of the structure 200 at different stages of fabrication according to embodiments of method 100 in FIG. 1. FIG. 11 is a diagram of magnetic field in and around the structure 200. FIG. 12 is a fragmentary schematic cross-sectional view of the structure 200. FIG. 13 is a fragmentary schematic cross-sectional view of a structure 300 fabricated according to embodiments of method 100 in FIG. 1. FIG. 14 is a fragmentary schematic cross-sectional view of a structure 400 fabricated according to embodiments of method 100 in FIG. 1. Method 100 is merely an example and is not intended to limit the present disclosure to what is explicitly illustrated in method 100. Additional steps can be provided before, during, and after method 100, and some steps described can be replaced, eliminated, or moved around for additional embodiments of method 100. Not all steps are described herein in detail for reasons of simplicity. Because the structure 200 (or 300, 400) will be fabricated into a semiconductor structure, the structure 200 (or 300, 400) may be referred to herein as a semiconductor structure 200 (or 300, 400) or a semiconductor device 200 (or 300, 400) as the context requires. For avoidance of doubts, the X, Y and Z directions in FIGS. 2-14 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Referring to FIGS. 1-2, method 100 includes a block 102 where a structure 200 is formed or provided. In some embodiments, the structure 200 includes a substrate 202, a circuitry structure 204 over the substrate 202, and a passivation structure 206 over the circuitry structure 204.

In one embodiment, the substrate 202 may be a silicon (Si) substrate. In some other embodiments, the substrate 202 may include other semiconductor materials such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure or a germanium-on-insulator (GeOI) structure. In some embodiments, the substrate 202 may include one or more well regions, such as n-type well regions doped with an n-type dopant (i.e., phosphorus (P) or arsenic (As)) or p-type well regions doped with a p-type dopant (i.e., boron (B)), for forming different types of devices. The n-type wells and the p-type wells may be formed using ion implantation or thermal diffusion.

In some embodiments, the circuitry structure 204 includes structures formed from front-end-of-line (FEOL) processing and back-end-of-the line (BEOL) processing. In some embodiments, the circuitry structure 204 includes a device layer 208 and a multilayer interconnect (MLI) structure 210 disposed over device layer 208. In some embodiments, the circuitry structure 204 includes a logic structure and may also be referred to as a logic structure 204.

The device layer 208 may be fabricated on and/or over the substrate 202 by front-end-of-line (FEOL) processing. Such FEOL processes may form various transistors and/or other types of devices on the substrate 202 to serve different functions. For example, these various transistors may form a central processing unit (CPU), a graphics process unit (GPU), access transistors for memory devices, or image signal processing (ISP) circuitry. The transistors may be planar transistors or multi-gate transistors. A planar device refers to a device having a gate structure that engages a planar surface of a semiconductor active region. A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT). The channel region of a GAA transistor may be formed from nanowires, nanosheets, or other nanostructures and for that reason, a GAA transistor may also be referred to as a nanowire transistor or a nanosheet transistor.

The device layer 208 may include passive microelectronic devices and/or active microelectronic devices, such as resistors, capacitors, inductors, diodes, PFETs, NFETs, MOSFETs, CMOS transistors, BJTs, LDMOS transistors, high voltage transistors, high frequency transistors, other devices, or combinations thereof. The various microelectronic devices can be configured to provide functionally distinct regions of an IC, such as a logic region (i.e., a core region), a memory region, an analog region, a peripheral region (e.g., an input/output region), a dummy region, another suitable region, or combinations thereof.

In some embodiments, the device layer 208 includes one or more dielectric layers. The one or more dielectric layers may include silicon oxide or a silicon oxide containing material. In some cases, the one or more dielectric layers may include undoped silicate glass (USG). In various examples, the one or more dielectric layers may be deposited by plasma enhanced CVD (PECVD), high-density plasma CVD (HDP-CVD), sub-atmospheric CVD (SACVD), ALD, PVD, or a combination thereof.

In some embodiments, the device layer 208 includes an interlayer dielectric (ILD) layer. The ILD layer may include silicon oxide, a silicon oxide containing material, or a low-k dielectric layer such as TEOS oxide, undoped silicate glass (USG), or doped silicon oxide such as BPSG, FSG, PSG, BSG, and/or other suitable low-k dielectric material. In various examples, the ILD layer may be deposited by chemical vapor deposition (CVD), physical vapor deposition (PVD), atomic layer deposition (ALD), or combinations thereof.

In some embodiments, the device layer 208 includes an etch stop layer (ESL). In some cases, the ESL includes a nitrogen-containing material and/or a carbon-containing material. For example, the ESL may include silicon carbon nitride (SiCN), silicon oxycarbide (SiOC), silicon carbide (SiC), silicon oxycarbonitride (SiOCN), silicon nitride (SiN), or combinations thereof. In various examples, the ESL may be deposited by CVD, ALD, PVD, or combinations thereof.

The MLI structure 210 may be fabricated on and/or over device layer 208 by middle-end-of-line (MEOL) processing and/or back-end-of-the line (BEOL) processing. In some embodiments, the MLI structure 210 is fabricated by the BEOL processing. The MLI structure 210 provides interconnections (e.g., wiring) between the various components formed within the device layer 208 and upper conductive features (e.g., conductive pads in the passivation structure, to be described).

In some embodiments, the MLI structure 210 includes about five (5) to about nineteen (19) metal layers (or metallization layers). In some embodiments, the metal layers of the MLI structure 210 each include an intermetal dielectric (IMD) layer and multiple vias and/or metal lines embedded in the IMD layer. Thicknesses of the IMD layers may decrease from top to bottom. For example, a thickness of a bottommost one of the plurality of the IMD layers is less than a thickness of at least one of the pluralities of the IMD layers above the bottommost one of the pluralities of the IMD layers. The vias and metal lines may be formed of one or more of titanium (Ti), ruthenium (Ru), nickel (Ni), cobalt (Co), copper (Cu), molybdenum (Mo), tungsten (W), or aluminum (Al). In one embodiment, they are formed of copper (Cu). In some embodiments, the metal lines and vias include a barrier layer and a bulk metal layer over the barrier layer. The IMD layer may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In some embodiments, the IMD layer includes a low-k dielectric material (having, for example, a dielectric constant that is less than a dielectric constant of silicon oxide (e.g., k < 3.9)). In some embodiments, the IMD layer includes silicon oxide.

In some embodiments, the metal layers of the MLI structure 210 each further include an etch stop layer (ESL) (e.g., below the IMD layer in the metal layer) and the multiple vias and/or metal lines in the metal layer may be also embedded in the ESL. In some embodiments, the IMD layers are interleaved by a plurality of the ESLs. The ESL may contain a material different than IMD layers, such as a dielectric material that is different than the dielectric material of the IMD layers. In some embodiments, the IMD layers include silicon oxide, the ESLs include silicon and nitrogen (for example, silicon nitride or silicon oxynitride). In some embodiments, a dielectric constant of at least one of the plurality of ESLs is greater than a dielectric constant of at least one of the plurality of IMD layers.

In some embodiments, the passivation structure 206 is formed over the MLI structure 210. The MLI structure 210 and the passivation structure 206 may collectively be referred to as an interconnection structure 217. In some embodiments, the passivation structure 206 includes multiple passivation layers. The multiple passivation layers may include a protection layer (e.g., 212-1, 212-2) including a nitrogen-containing material and/or a carbon-containing material. For example, the protection layer may include SiCN, SiOC, SiC, SiOCN, SiN, or combinations thereof. In various examples, the protection layer may be deposited by CVD, ALD, PVD, or combinations thereof. In some embodiments, the protection layer may protect the top metal lines in the MLI structure 210 from being oxidized.

The multiple passivation layers may further include a plasma-enhanced oxide (PEOX) layer (e.g., 214-1, 214-2) formed over the protection layer. In some embodiments, the PEOX layer may include silicon oxide or a silicon oxide containing material. In some cases, the PEOX layer may include undoped silicate glass (USG). The PEOX layer may be deposited by PECVD, HDP-CVD, SACVD, ALD, PVD, or a combination thereof.

In some embodiments, the multiple passivation layers further include a polymer layer 216. The polymer layer 216 may be formed over the protection layer(s). In some embodiments, the polymer layer 216 is a topmost layer of the passivation structure 206. In some embodiments, the polymer layer 216 includes epoxy, polyimide (PI), benzocyclobutene (BCB), polybenzoxazole (PBO), or a combination thereof. In some embodiments, the polymer layer 216 includes PI and is referred to as a PI layer. The polymer layer 216 may be deposited over the protection layer using a suitable deposition technique, such as spin-coating or a vapor-deposition process (VDP).

In some embodiments, the passivation structure 206 further includes conductive pads embedded in the multiple passivation layers. In some embodiments, the conductive pads are not directly under the inductor(s) (to be formed and described). For example, the conductive pads are disposed out of a boundary of a magnetic layer of the inductor(s) in a top view (to be described). The conductive pads may include a conductive material including copper, cobalt, nickel, aluminum, tungsten, titanium, silver, or a combination thereof. In some embodiments, the conductive pads include copper and silver. The conductive pads may have any suitable shape and may be formed using any suitable methods. For example, an opening may be formed using a patterning and an etching process (e.g., such as a dry etching process, a wet etching process, or a combination thereof) in the multiple passivation layers, and the conductive material is deposited into the opening using a suitable deposition technique, such as ALD, PVD, or CVD. In the depicted embodiment, a CMP process may be performed to remove excess materials. The conductive pads may be exposed or be covered by at least one of the multiple passivation layers.

Still referring to FIGS. 1-2, method 100 includes a block 104 where a first isolation layer 218 is deposited over the passivation structure 206, and a first magnetic layer 220 is deposited over the first isolation layer 218.

The first isolation layer 218 may have a multi-layer structure and may include one or more dielectric layers as depicted. In some embodiments, the one or more dielectric layers of the first isolation layer 218 include an ESL. The ESL may be made of or include tantalum oxide, zirconium oxide, tantalum nitride, titanium, one or more other suitable materials, or a combination thereof. In some embodiments, the ESL may include a topmost layer of the first isolation layer 218. In some embodiments, the one or more dielectric layers of the first isolation layer 218 include polyimide, silicon nitride (SiN), silicon carbide (SiC), aluminum oxide (Al₂O₃), silicon oxide (e.g., SiO₂), tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), other suitable dielectric materials, or a combination thereof. In one embodiment, the one or more dielectric layers of the first isolation layer 218 include silicon oxide. The one or more dielectric layers of the first isolation layer 218 may be deposited sequentially over the passivation structure 206 using any suitable methods, such as chemical vapor deposition (CVD), physical vapor deposition (PVD), atomic layer deposition (ALD), flowable CVD (FCVD), high density plasma CVD (HDPCVD), metal organic CVD (MOCVD), remote plasma CVD (RPCVD), plasma enhanced CVD (PECVD), low-pressure CVD (LPCVD), atomic layer CVD (ALCVD), atmospheric pressure CVD (APCVD), plasma enhanced ALD (PEALD), other suitable methods, or combinations thereof. In some embodiments, the first isolation layer 218 is deposited by CVD.

Still referring to FIGS. 1-2, a first magnetic layer 220 is deposited over the first isolation layer 218. The first magnetic layer 220 extends horizontally along a top surface of the first isolation layer 218. The first magnetic layer 220 may include a multilayer structure. In some embodiments, the first magnetic layer 220 includes a lamination film. The first magnetic layer 220 may include one or more sub-layers. In some embodiments, the first magnetic layer 220 includes one or more magnetic materials, such as cobalt (Co), iron (Fe), boron (B), another magnetic material, or a combination thereof. In some embodiments, the first magnetic layer 220 includes a cobalt alloy (e.g., cobalt-zirconium-tantalum (CoZrTa (also referred to as CZT), CoZr, and/or the like), an iron alloy, a nickel alloy (e.g., nickel-iron (NiFe) and/or the like), or a combination thereof. In some embodiments, the first magnetic layer 220 includes cobalt, zirconium, tantalum, iron, nickel, or a combination thereof. In some embodiments, the first magnetic layer 220 includes CoZrTa. The first magnetic layer 220 may be deposited by any suitable methods, such as a PVD process, a CVD process, an ALD process, one or more other applicable processes, or a combination thereof.

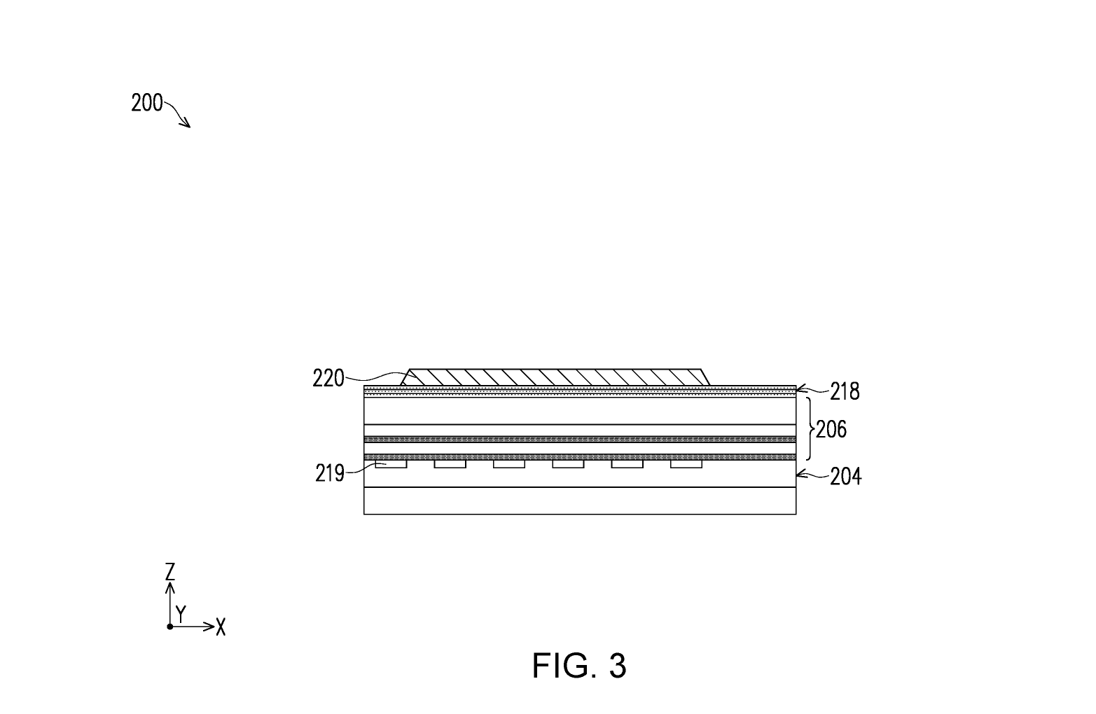

Referring to FIGS. 1 and 3, method 100 includes a block 106 where the first magnetic layer 220 is patterned. A patterned mask layer (not explicitly depicted) may be formed over the first magnetic layer 220 to assist in a subsequent patterning process of the first magnetic layer 220. In some embodiments, the patterning at block 106 includes a combination of photolithography and etch steps. For example, at least one hard mask is deposited over the first magnetic layer 220 using CVD, flowable CVD (FCVD), or a suitable process. A photoresist layer is then deposited over the at least one hard mask layer using spin-on coating. The deposited photoresist layer may undergo a pre-exposure baking process, exposure to radiation reflected from or transmitted through a photomask, a post-exposure baking process, and developing process, so as to form a patterned photoresist. The at least one hard mask layer is then etched using the patterned photoresist as an etch mask to form a patterned hard mask. The patterned hard mask is then applied as an etch mask to etch the first magnetic layer 220. In some embodiments, in a top view, the patterned first magnetic layer 220 may have a square shape, a rectangular shape, or another suitable shape. In some embodiments, etching the first magnetic layer 220 includes a wet etching process. The etchant used in the wet etching process may include nitric acid, hydrochloric acid, hydrofluoric acid, one or more other suitable etchants, or a combination thereof. For example, a mixture of nitric acid, hydrochloric acid, and hydrofluoric acid is used in the wet etching process. The first isolation layer 218 may include and/or act as an etch stop layer in the etching process, and protect the lower features (e.g., the passivation structure 206) from being damaged during the wet etching process for patterning the first magnetic layer 220. In some embodiments, an etch stop layer may be removed from parts of the first isolation layer 218 that are laterally outside of the patterned first magnetic layer 220. After the etching process, sidewalls of the first magnetic layer 220 may be vertical or tilted. In some embodiments, the first magnetic layer 220 has a trapezoid shape in a cross-sectional view as depicted in FIG. 3. In some embodiments, lower layer(s) of the one or more sub-layers in the first magnetic layer 220 are wider than the upper layer(s) of the one or more sub-layers along the X direction. For example, widths of the one or more sub-layers along the X direction gradually decrease from bottom to top.

In some embodiments, the structure 200 includes underlying conductive features 219 in the circuitry structure 204 and extending lengthwise along the Y direction. The underlying conductive features 219 may be directly below the patterned first magnetic layer 220. The underlying conductive features 219 may be a portion of the metal lines in the MLI structure 210. In some embodiments, the underlying conductive features 219 are in a topmost metal layer of the MLI structure 210. In some other embodiments, the underlying conductive features 219 are not included in the structure 200. Although not depicted in all of the following figures, it is understood that the underlying conductive features 219 may be included in the MLI structure 210.

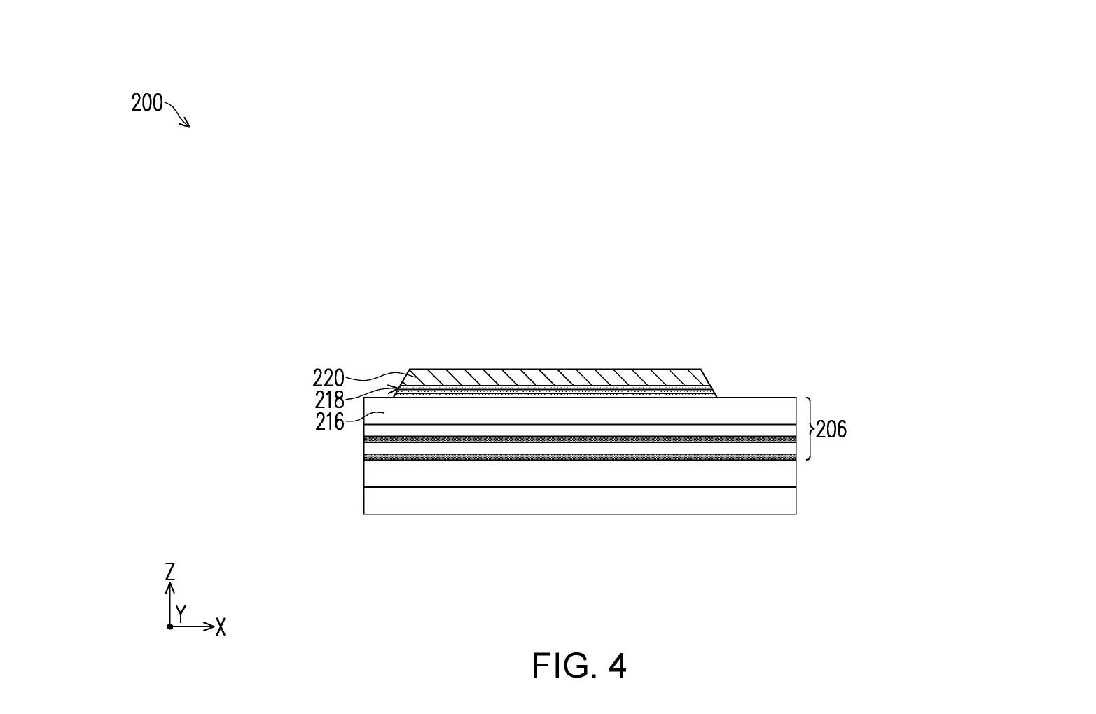

Referring to FIGS. 1 and 4, method 100 includes a block 108 where the first isolation layer 218 is patterned using the patterned first magnetic layer 220 and/or the patterned mask layer as a mask. Appropriate etch process at block 108 may be a dry etch process, a wet etch process, or a combination thereof. In some embodiments, the etch process at block 108 may be a dry etch process (e.g., a reactive ion etching (RIE) process) that includes use of an oxygen-containing gas (e.g., O₂), a fluorine-containing gas (e.g., SF₆ or NF₃), or a chlorine-containing gas (e.g., Cl₂ and/or BCl₃). The polymer layer 216 may act as an etch stop layer in the etching process and protect the lower structures of the passivation structure 206 from being damaged during the etching process.

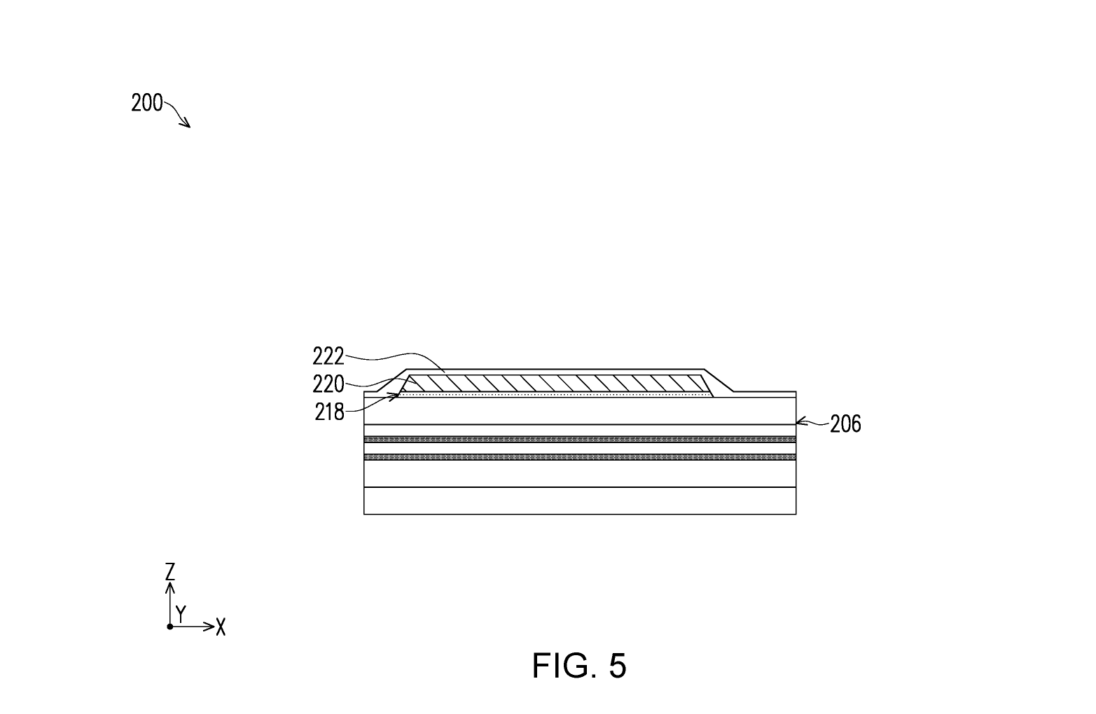

Referring to FIGS. 1 and 5, method 100 includes a block 110 where a second isolation layer 222 is formed over the first magnetic layer 220, the first isolation layer 218, and the passivation structure 206. The second isolation layer 222 may include suitable dielectric materials, such as polyimide, silicon nitride (SiN), silicon carbide (SiC), aluminum oxide (Al₂O₃), silicon oxide (e.g., SiO₂), tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), other suitable dielectric materials, or a combination thereof. In some embodiments, the second isolation layer 222 includes polyimide. The second isolation layer 222 may be deposited using a suitable method such as those described in depositing the first isolation layer 218. The second isolation layer 222 on sidewalls of the first magnetic layer 220 and the first isolation layer 218 may be thicker than the second isolation layer 222 on top surfaces of the first magnetic layer 220 and the passivation structure 206.

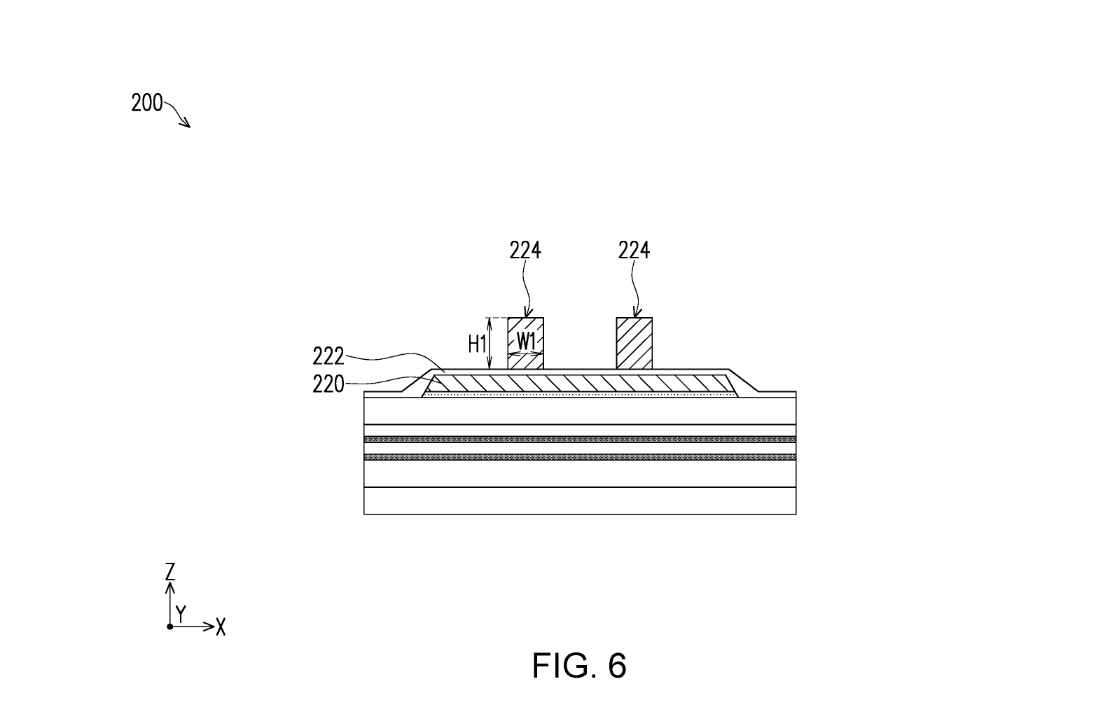

Referring to FIGS. 1 and 6, method 100 includes a block 112 where conductive lines 224 are formed over the second isolation layer 222. The conductive lines 224 may also be referred to as post passivation interconnect (PPI) 224. In some embodiments, two conductive lines 224 are formed. The two conductive lines 224 may correspond to an input of the inductor (e.g., Vin) and an output from the inductor (e.g., Vout). In some embodiments, the conductive lines 224 include copper (Cu), cobalt, nickel, aluminum, tungsten, titanium, or a combination thereof. In some embodiments, the conductive lines 224 include Cu. The conductive lines 224 may be formed using any suitable methods, such as CVD, PVD, ALD, plating, stripping, seed etch, sputtering, evaporation, electroplating, printing, or a combination thereof.

The conductive lines 224 may have a height of H1 of about 20µm to about 100µm along the Z direction. The height H1 may be adjusted to meet design parameters (e.g., resistance and modulus of the conductive lines 224). If H1 is too small, resistance of the conductive lines 224 may be too large, which may increase energy waste during operation of the structure 200. If H1 is too large, it may unnecessarily increase the material of the conductive lines 224 and the costs associated therewith. In some embodiments, a width W1 of the conductive lines 224 along the X direction is about 20µm to about 100µm. If W1 is too small, capability of the conductive lines 224 to sustain stress may be too small. If W1 is too large, it may unnecessarily increase the footprint of the conductive lines 224 and the costs associated therewith.

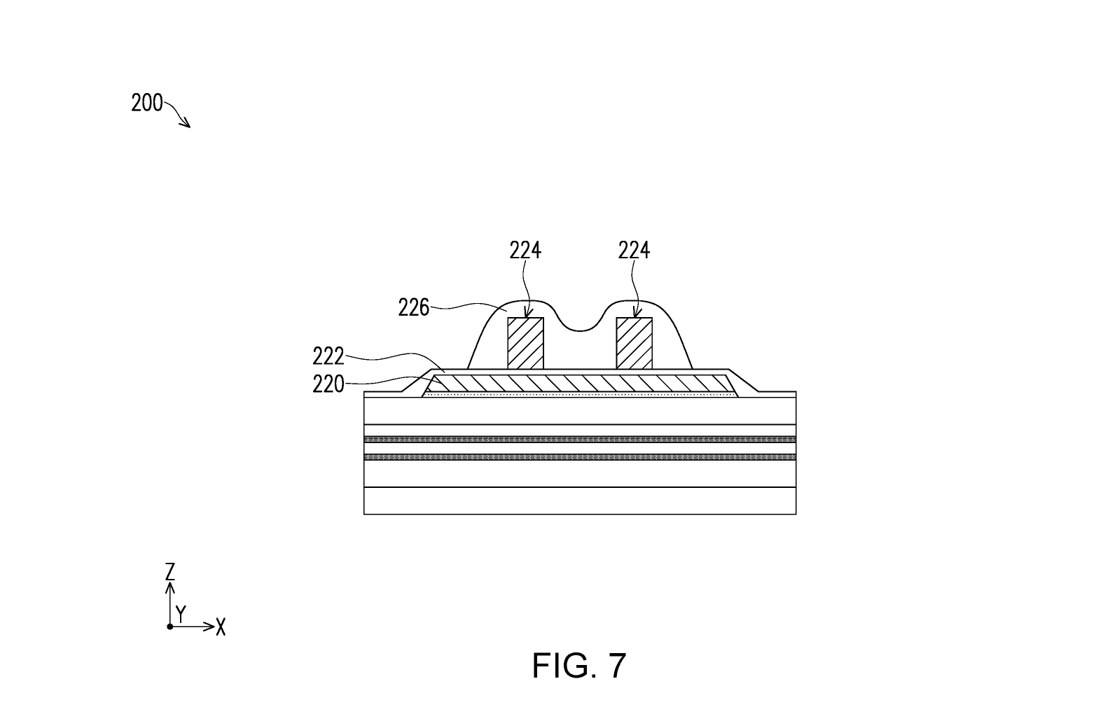

Referring to FIGS. 1 and 7, method 100 includes a block 114 where a third isolation layer 226 is formed over the conductive lines 224 and the second isolation layer 222. The third isolation layer 226 fills space between the conductive lines 224. In some embodiments, the third isolation layer 226 is disposed on top surfaces and sidewalls of the conductive lines 224, such that the conductive lines 224 are embedded in the third isolation layer 226. In some embodiments, an outline of top surfaces of the third isolation layer 226 has a hilly shape with a groove (e.g., in the middle of the outline) as depicted. The third isolation layer 226 may isolate the conductive lines 224 from a second magnetic layer (to be described) and provide a support for the second magnetic layer. In some embodiments, the third isolation layer 226 includes one or more insulating and/or dielectric materials, such as silicon mononitride (SiN), silicon dioxide (SiO), a polymer (e.g., epoxy, PI, BCB, PBO), and/or the like, or a combination thereof. In some embodiments, the third isolation layer 226 includes PI. The third isolation layer 226 may be deposited using any suitable method, such as those described in depositing the first isolation layer 218.

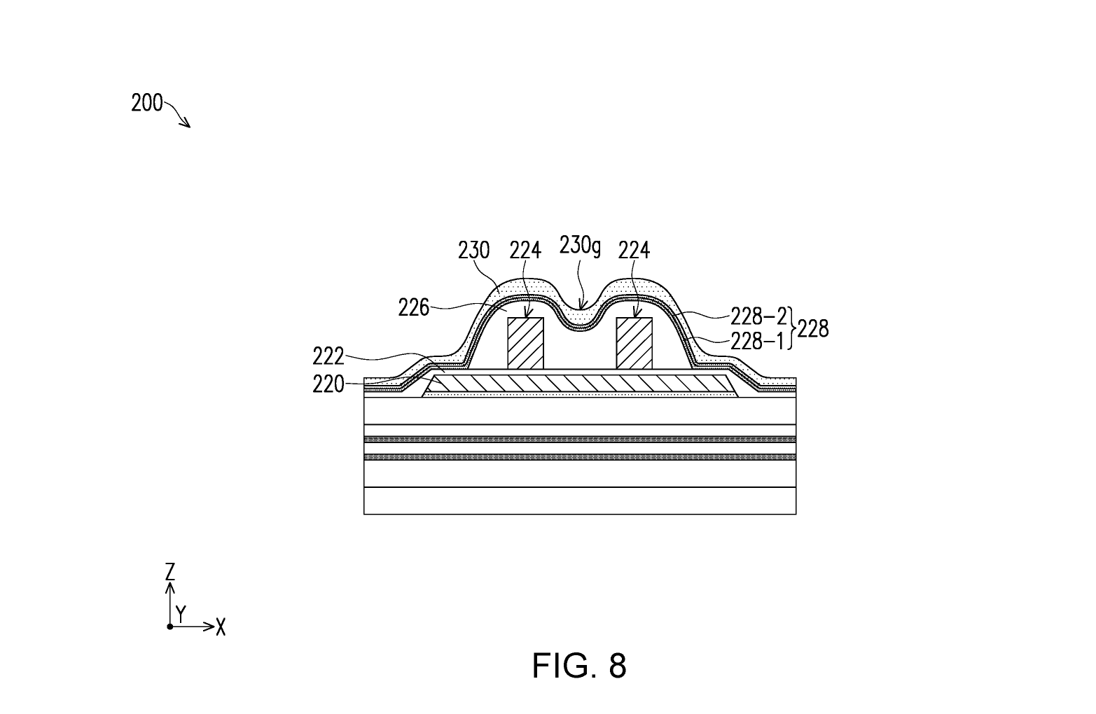

Referring to FIGS. 1 and 8, method 100 includes a block 116 where a fourth isolation layer 228 is deposited over the third isolation layer 226 and the second isolation layer 222. The fourth isolation layer 228 may include dielectric materials and may have a multilayer structure. In the depicted embodiment, the fourth isolation layer 228 includes a first sub-layer 228-1 and a second sub-layer 228-2 over the first sub-layer 228-1. In some embodiments, the first sub-layer 228-1 includes silicon nitride. The second sub-layer 228-2 may be an etch stop layer (ESL) and may include similar materials as the ESL in the first isolation layer 218 described above. The fourth isolation layer 228 may be deposited over the third isolation layer 226 and the second isolation layer 222. The fourth isolation layer 228 may trace the outline of the third isolation layer 226 and exposed surfaces of the second isolation layer 222 and may have a stepped profile accordingly. In various examples, the fourth isolation layer 228 may be deposited using any suitable method, such as those described in depositing the first isolation layer 218.

Still referring to FIGS. 1 and 8, method 100 includes a block 118 where a second magnetic layer 230 is deposited over the fourth isolation layer 228. The second magnetic layer 230 may include a multilayer structure. In some embodiments, the second magnetic layer 230 includes a lamination film. In some embodiments, the second magnetic layer 230 may trace the profile of the fourth isolation layer 228 and have a hilly shape with a groove 230g. A bottom surface of the second magnetic layer 230 above the first magnetic layer 220 is separated from the first magnetic layer 220 by the second isolation layer 222 and the fourth isolation layer 228. In some embodiments, the second magnetic layer 230 includes one or more magnetic materials, such as those described above for the first magnetic layer 220. In some embodiments, the second magnetic layer 230 includes CoZrTa. In some embodiments, the fourth isolation layer 228 may laterally extend past opposing outermost edges of the second magnetic layer 230.

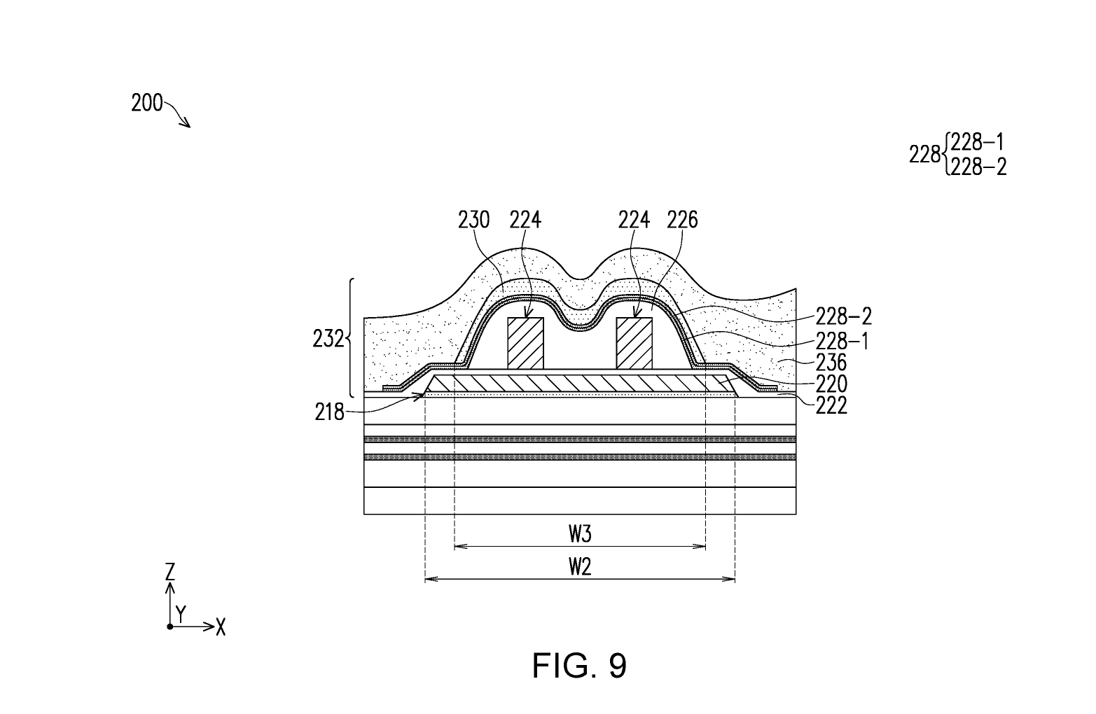

Referring to FIGS. 1 and 9-10, method 100 includes a block 120 where the second magnetic layer 230 is patterned. FIG. 10 illustrates a fragmentary top view of the structure 200. FIG. 9 is a fragmentary cross-sectional view of the structure 200 taken along line A-A’ as in FIG. 10. The second magnetic layer 230 may be patterned using similar methods as operations at block 106. The fourth isolation layer 228 may act as an etch stop layer in the etching process. In some embodiments, after patterning, a width W2 of the first magnetic layer 220 is greater than a width W3 of the second magnetic layer 230 along the X direction. For example, sidewalls of the first magnetic layer 220 extend laterally beyond outer sidewalls of the second magnetic layer 230. In some embodiments, after patterning, the second magnetic layer 230 excludes a horizontal portion that extends lengthwise along a top surface of the fourth isolation layer 228 as depicted in FIG. 9. In some other embodiments, the second magnetic layer 230 includes the horizontal portion, and the first magnetic layer 220 extends laterally beyond the horizontal portion.

Referring to FIG. 10, in some embodiments, the first magnetic layer 220 and the second magnetic layer 230 each have a rectangular footprint. In some embodiments, along the Y direction, a width W4 of the first magnetic layer 220 is greater than a width W5 of the second magnetic layer 230. In some embodiments, in the top view, end portions of the conductive lines 224 are out of boundaries of the first magnetic layer 220. The end portions may be electrically connected to conductive pads 234. The conductive pads 234 may be disposed out of a boundary of the first magnetic layer 220 and embedded in the passivation structure 206 as described above.

Referring to FIGS. 1 and 9, method 100 includes a block 122 where the fourth isolation layer 228 is patterned. In some embodiments, the patterning at block 122 includes a combination of photolithography and etch steps. The etching may include a dry etch process, a wet etch process, or a combination thereof similar as the etching at block 108. The second isolation layer 222 may act as an etch stop layer.

After patterning, the first magnetic layer 220, the conductive lines 224, the second magnetic layer 230, the first isolation layer 218, the third isolation layer 226, the fourth isolation layer 228, and a portion of the second isolation layer 222 below the fourth isolation layer 228 collectively form an inductor 232 or an inductive structure 232.

Still referring to FIGS. 1 and 9, method 100 includes a block 124 where a fifth isolation layer 236 is formed over the exposed surfaces of the structure 200 (e.g., the second magnetic layer 230). The fifth isolation layer 236 may include a dielectric material, such as silicon mononitride (SiN), silicon dioxide (SiO), a polymer (e.g., epoxy, PI, BCB, PBO), and/or the like, or a combination thereof. In some embodiments, the fifth isolation layer 236 includes PI. The fifth isolation layer 236 may isolate the features therebelow and protect the features therebelow from environment (e.g., moisture).

FIG. 11 illustrates an example diagram of magnetic field in and around the structure 200 during operation of the structure 200. FIG. 11 may be from measurement and/or simulation. During operation, magnetic field may exist (e.g., be generated) in and around the structure 200. By having the first magnetic layer 220 and the second magnetic layer 230 as disclosed herein, opposite magnetic field may be generated, and most of leakage of magnetic field from the inductor 232 is in a space above the inductor 232, thus reducing EMI effect between the inductor and the features below the first magnetic layer 220. The underlying conductive features 219 may further reduce the EMI effect between the inductor and the features below the underlying conductive features 219. Thus, EMI between the inductor 232 and the devices and features in the circuitry structure 204 below the inductor 232 may be reduced. The reduced EMI effect may reduce the resistance of the inductor 232 (e.g., by a range of between approximately 5% and approximately 15%, by approximately 10%, by approximately 10.7%, or other similar values) and increase inductance of the inductor 232 (e.g., by a range of between approximately 1% and approximately 5%, by approximately 3%, by approximately 2.6%, or other similar values).

The magnetic field inside the inductor 232 may be greater (or stronger) than the magnetic field outside the inductor 232 on average. In some embodiments, an average magnetic field inside the inductor 232 is stronger than a magnetic field above the inductor 232 (e.g., at the groove 230g). The magnetic field above the inductor 232 may be stronger than a magnetic field below the inductor 232 (e.g., in the circuitry structure 204). In some embodiments, the magnetic field of the inductor 232 leaks from an opening S1 between an edge 230e of the second magnetic layer 230 and an edge 220e of the first magnetic layer 220, and into a space near the edges (e.g., in an area B as depicted). Most of the area B is above the opening S1 rather than below the opening S1. This may result from the first magnetic layer 220 being wider than the second magnetic layer 230, thus opposite magnetic field distribution is provided. In some embodiments, a magnetic field above the edges 230e is stronger than a magnetic field below the edge 220e. For example, a point C is at a distance H2 above a bottom surface of the edge 230e, and a point D is at a same distance H2 below a top surface of the edge 220e. In the depicted embodiment, the first magnetic field at the point C is stronger than a second magnetic field at the point D. The first magnetic field and the second magnetic field are less or weaker than a third magnetic field at a point E between the edges 230e and 220e. A fourth magnetic field in a region F below the underlying conductive features 219 is weaker than the second magnetic field at the point D.

Referring to FIG. 12, a schematic fragmentary cross-sectional view of the structure 200 is illustrated. A combined structure 205 includes the circuitry structure 204 and the passivation structure 206. In some embodiments, the edge 230e and the edge 220e have a horizontal distance D1 of about 20 µm to about 100µm. D1 is independent from the width W2 or the width W3 in FIGS. 9 and 10. If D1 is too small, the EMI effect may not be reduced or may be insufficiently reduced. If D1 is too large, it may unnecessarily increase the material of the first magnetic layer 220 and the costs associated therewith.

Referring to FIG. 13, a schematic fragmentary cross-sectional view of a structure 300 is illustrated. The structure 300 may be fabricated by method 100. The structure 300 includes the substrate 202, the combined structure 205 over the substrate 202, and two inductors 238 similar to the inductor 232 described above. The second isolation layer 222 extends continuously from one inductor 238 to the other inductor 238. In some embodiments, a distance between the first magnetic layers 220 of the two inductors 238 is D2 as depicted. D2 may be in a range of about 20µm to about 1,000µm. D2 is independent from the width W2 or the width W3. If D2 is too small, the EMI effect between the two inductors 238 may be too large. If D2 is too large, the footprint of the structure 300 may be too large, and the cost and time associated therewith may be too much. The structure 300 may include the underlying conductive features 219 as described above in the combined structure 205 and directly below the two inductors 238.

Referring to FIG. 14, a schematic fragmentary cross-sectional view of a structure 400 is illustrated. The structure 400 may be fabricated by method 100. The structure 400 includes the substrate 202 and the combined structure 205 over the substrate 202, and two inductors 240. Differences from the structure 300 include the following. In some embodiments, compared to the inductors 238, the two inductors 240 share a first isolation layer 218’, a first magnetic layer 220’, a second isolation layer 222’, and a fourth isolation layer 228’. The first isolation layer 218’, the first magnetic layer 220’, the second isolation layer 222’, and the fourth isolation layer 228’ each extend continuously from one inductor 240 to the other inductor 240. The first isolation layer 218’, the first magnetic layer 220’, the second isolation layer 222’, and the fourth isolation layer 228’ may have similar composition and are made using similar methods as the first isolation layer 218, the first magnetic layer 220, the second isolation layer 222, and the fourth isolation layer 228 as descried above, respectively. A distance between the second magnetic layers 230 of the two inductors 240 is D3 in a range of about 20µm to about 100µm. D3 is independent from the width W2 or the width W3. If D3 is too small, the EMI effect between the two inductors 240 may be too large. If D3 is too large, the material of the first magnetic layer 220’ and the costs associated therewith may be too much. The structure 400 may include the underlying conductive features 219 as described above in the combined structure 205 and directly below the two inductors 240.

Although the inductors described above are disposed over a combined structure 205 or a passivation structure 206, the inductors may be applied over other semiconductor structures.

Although not intended to be limiting, one or more embodiments of the present disclosure provide many benefits to a semiconductor structure. For example, the present disclosure provides semiconductor structures having less EMI effect, reduced inductor resistance, and increased inductance. For example, by having the first magnetic layer wider than the second magnetic layer and/or the underlying conductive features, opposite magnetic field distribution may be generated, thus reducing the EMI effect between the inductors and features therebelow (e.g., the underlying conductive features, the devices). Thus, the overall performance of the semiconductor structure may be improved.

In one exemplary aspect, the present disclosure is directed to a semiconductor structure. The semiconductor structure includes a substrate, a multilayer interconnect (MLI) structure over the substrate, a passivation layer over the MLI structure, a first magnetic layer over the passivation layer, a first dielectric layer over the first magnetic layer and the passivation layer, conductive lines on the first dielectric layer, above the first magnetic layer, and extending lengthwise along a first direction, a second dielectric layer around and over the conductive lines, and a second magnetic layer around and over the second dielectric layer. The first magnetic layer extends a first width along a second direction different from the first direction, the second magnetic layer extends a second width less than the first width along the second direction.

In some embodiments, at an edge of the first magnetic layer, a first magnetic field above the first magnetic layer is greater than a second magnetic field below the first magnetic layer. In some embodiments, the MLI structure comprises a plurality of intermetal dielectric (IMD) layers interleaved by a plurality of etch stop layers (ESLs), a dielectric constant of at least one of the plurality of ESLs is greater than a dielectric constant of at least one of the plurality of IMD layers, the semiconductor structure further comprises a plurality of conductive features in the MLI structure. In some embodiments, a sidewall of the first magnetic layer extends to beyond an outer sidewall of the second magnetic layer by a distance of about 20 µm to about 100 µm. In some embodiments, the conductive lines are first conductive lines, the semiconductor structure further includes a third magnetic layer over the passivation layer, a third dielectric layer over the third magnetic layer, second conductive lines on the third dielectric layer, above the third magnetic layer, and extending lengthwise along the first direction, a fourth dielectric layer around and over the second conductive lines, and a fourth magnetic layer around and over the fourth dielectric layer. A distance between the first magnetic layer and the third magnetic layer is about 20 µm to about 1,000 µm. In some embodiments, a sidewall of the third magnetic layer extends to beyond an outer sidewall of the fourth magnetic layer by a distance of about 20 µm to about 100 µm. In some embodiments, the conductive lines are first conductive lines, the semiconductor structure further includes second conductive lines on the first dielectric layer, above the first magnetic layer, and extending lengthwise along the first direction, a third dielectric layer around and over the second conductive lines, and a third magnetic layer around and over the third dielectric layer. The third magnetic layer is spaced apart from the second magnetic layer by a distance of about 20 µm to about 100 µm. In some embodiments, the semiconductor structure further includes a fourth dielectric layer disposed between the second dielectric layer and the second magnetic layer, and between the third dielectric layer and the third magnetic layer.

In another exemplary aspect, the present disclosure is directed to a method. The method includes forming a first magnetic layer over a first dielectric layer, depositing a second dielectric layer over the first magnetic layer and the first dielectric layer, forming a first conductive feature and a second conductive feature over the second dielectric layer and the first magnetic layer, forming a third dielectric layer around and over the first conductive feature and the second conductive feature, and forming a second magnetic layer over the third dielectric layer. In a top view, the first magnetic layer extends beyond a boundary of the second magnetic layer.

In some embodiments, the method further includes forming a fourth dielectric layer over the second magnetic layer and the second dielectric layer. In some embodiments, before forming the second magnetic layer and after forming the third dielectric layer, the method further includes forming a fourth dielectric layer over the second dielectric layer and the third dielectric layer. The second magnetic layer is formed over the fourth dielectric layer, in the top view, the fourth dielectric layer extends beyond a boundary of the first magnetic layer. In some embodiments, the method further includes forming a plurality of metal lines in the first dielectric layer, at least a portion of the metal lines are directly below the first magnetic layer. In some embodiments, in the top view, the first conductive feature and the second conductive feature include end portions out of a boundary of the first magnetic layer, the end portions are connected to conductive pads in the first dielectric layer. In some embodiments, in the top view, the second magnetic layer is within a boundary of the first magnetic layer. In some embodiments, the method further includes forming a third conductive feature and a fourth conductive feature over the second dielectric layer and the first magnetic layer, forming a fourth dielectric layer around and over the third conductive feature and the fourth conductive feature, and forming a third magnetic layer over the fourth dielectric layer. In a top view, the first magnetic layer extends beyond a boundary of the third magnetic layer, the third magnetic layer is spaced apart from the second magnetic layer. In some embodiments, the method further includes forming a third magnetic layer over the first dielectric layer, the second dielectric layer is further deposited over the third magnetic layer, and the method further includes forming a third conductive feature and a fourth conductive feature over the second dielectric layer and the third magnetic layer, forming a fourth dielectric layer around and over the third conductive feature and the fourth conductive feature, and forming a fourth magnetic layer over the fourth dielectric layer. In a top view, the third magnetic layer extends beyond a boundary of the fourth magnetic layer, the third magnetic layer is spaced apart from the first magnetic layer.

In yet another exemplary aspect, the present disclosure is directed to a method. The method includes providing a structure comprising a device layer and an interconnection structure over the device layer, forming a first magnetic layer over the interconnection structure, forming a first dielectric layer over the first magnetic layer and the interconnection structure, forming conductive lines over the first dielectric layer and above the first magnetic layer, forming a second dielectric layer over the conductive lines, thereby filling space between the conductive lines depositing a second magnetic layer over the second dielectric layer, and patterning the second magnetic layer. After patterning the second magnetic layer, edges of the second magnetic layer are above the first magnetic layer, the interconnection structure comprises a plurality of intermetal dielectric layers interleaved by a plurality of etch stop layers, a dielectric constant of at least one of the plurality of etch stop layers is greater than a dielectric constant of at least one of the plurality of intermetal dielectric layers.

In some embodiments, before forming the first magnetic layer, the method further includes forming a third dielectric layer over the interconnection structure, the first magnetic layer is formed over the third dielectric layer. In some embodiments, after patterning the second magnetic layer, the method further includes forming a third dielectric layer over the second magnetic layer and the first dielectric layer. In some embodiments, the method further includes before depositing the second magnetic layer, forming a third dielectric layer over the second dielectric layer, and after patterning the second magnetic layer, patterning the third dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a multilayer interconnect (MLI) structure over the substrate;
a passivation layer over the MLI structure;
a first magnetic layer over the passivation layer;
a first dielectric layer over the first magnetic layer and the passivation layer;
conductive lines on the first dielectric layer, above the first magnetic layer, and extending lengthwise along a first direction;
a second dielectric layer around and over the conductive lines; and
a second magnetic layer around and over the second dielectric layer,
wherein the first magnetic layer extends a first width along a second direction different from the first direction,
wherein the second magnetic layer extends a second width less than the first width along the second direction.

2. The semiconductor structure of claim 1, wherein at an edge of the first magnetic layer, a first magnetic field above the first magnetic layer is greater than a second magnetic field below the first magnetic layer.

3. The semiconductor structure of claim 1, wherein the MLI structure comprises a plurality of intermetal dielectric (IMD) layers interleaved by a plurality of etch stop layers (ESLs),
wherein a dielectric constant of at least one of the plurality of ESLs is greater than a dielectric constant of at least one of the plurality of IMD layers,
wherein the semiconductor structure further comprises a plurality of conductive features in the MLI structure.

4. The semiconductor structure of claim 1, wherein a sidewall of the first magnetic layer extends to beyond an outer sidewall of the second magnetic layer by a distance of about 20µm to about 100µm.

5. The semiconductor structure of claim 1, wherein the conductive lines are first conductive lines;
wherein the semiconductor structure further comprises:
a third magnetic layer over the passivation layer,
a third dielectric layer over the third magnetic layer,
second conductive lines on the third dielectric layer, above the third magnetic layer, and extending lengthwise along the first direction,
a fourth dielectric layer around and over the second conductive lines, and
a fourth magnetic layer around and over the fourth dielectric layer; and
wherein a distance between the first magnetic layer and the third magnetic layer is about 20µm to about 1,000µm.

6. The semiconductor structure of claim 5, wherein a sidewall of the third magnetic layer extends to beyond an outer sidewall of the fourth magnetic layer by a distance of about 20µm to about 100µm.

7. The semiconductor structure of claim 1, wherein the conductive lines are first conductive lines;
wherein the semiconductor structure further comprises:
second conductive lines on the first dielectric layer, above the first magnetic layer, and extending lengthwise along the first direction,
a third dielectric layer around and over the second conductive lines, and
a third magnetic layer around and over the third dielectric layer; and
wherein the third magnetic layer is spaced apart from the second magnetic layer by a distance of about 20 µm to about 100 µm.

8. The semiconductor structure of claim 7, further comprising a fourth dielectric layer disposed between the second dielectric layer and the second magnetic layer, and between the third dielectric layer and the third magnetic layer.

9. A method, comprising:
forming a first magnetic layer over a first dielectric layer;
depositing a second dielectric layer over the first magnetic layer and the first dielectric layer;
forming a first conductive feature and a second conductive feature over the second dielectric layer and the first magnetic layer;
forming a third dielectric layer around and over the first conductive feature and the second conductive feature; and
forming a second magnetic layer over the third dielectric layer,
wherein in a top view, the first magnetic layer extends beyond a boundary of the second magnetic layer.

10. The method of claim 9, further comprising forming a fourth dielectric layer over the second magnetic layer and the second dielectric layer.

11. The method of claim 9, before forming the second magnetic layer and after forming the third dielectric layer, further comprising forming a fourth dielectric layer over the second dielectric layer and the third dielectric layer,
wherein the second magnetic layer is formed over the fourth dielectric layer,
wherein in the top view, the fourth dielectric layer extends beyond a boundary of the first magnetic layer.

12. The method of claim 9, further comprising forming a plurality of metal lines in the first dielectric layer,
wherein at least a portion of the metal lines are directly below the first magnetic layer.

13. The method of claim 9, wherein in the top view, the first conductive feature and the second conductive feature include end portions out of a boundary of the first magnetic layer,
wherein the end portions are connected to conductive pads in the first dielectric layer.

14. The method of claim 9, wherein in the top view, the second magnetic layer is within a boundary of the first magnetic layer.

15. The method of claim 9, further comprising:
forming a third conductive feature and a fourth conductive feature over the second dielectric layer and the first magnetic layer;
forming a fourth dielectric layer around and over the third conductive feature and the fourth conductive feature; and
forming a third magnetic layer over the fourth dielectric layer,
wherein in a top view, the first magnetic layer extends beyond a boundary of the third magnetic layer,
wherein the third magnetic layer is spaced apart from the second magnetic layer.

16. The method of claim 9, further comprising forming a third magnetic layer over the first dielectric layer;
wherein the second dielectric layer is further deposited over the third magnetic layer; and
wherein the method further comprises:
forming a third conductive feature and a fourth conductive feature over the second dielectric layer and the third magnetic layer,
forming a fourth dielectric layer around and over the third conductive feature and the fourth conductive feature, and
forming a fourth magnetic layer over the fourth dielectric layer,
wherein in a top view, the third magnetic layer extends beyond a boundary of the fourth magnetic layer,
wherein the third magnetic layer is spaced apart from the first magnetic layer.

17. A method, comprising:
providing a structure comprising a device layer and an interconnection structure over the device layer;
forming a first magnetic layer over the interconnection structure;
forming a first dielectric layer over the first magnetic layer and the interconnection structure;
forming conductive lines over the first dielectric layer and above the first magnetic layer;
forming a second dielectric layer over the conductive lines, thereby filling space between the conductive lines;
depositing a second magnetic layer over the second dielectric layer; and
patterning the second magnetic layer,
wherein after patterning the second magnetic layer, edges of the second magnetic layer are above the first magnetic layer,
wherein the interconnection structure comprises a plurality of intermetal dielectric layers interleaved by a plurality of etch stop layers,
wherein a dielectric constant of at least one of the plurality of etch stop layers is greater than a dielectric constant of at least one of the plurality of intermetal dielectric layers.

18. The method of claim 17, before forming the first magnetic layer, further comprising forming a third dielectric layer over the interconnection structure,
wherein the first magnetic layer is formed over the third dielectric layer.

19. The method of claim 17, after patterning the second magnetic layer, further comprising forming a third dielectric layer over the second magnetic layer and the first dielectric layer.

20. The method of claim 17, further comprising:
before depositing the second magnetic layer, forming a third dielectric layer over the second dielectric layer, and
after patterning the second magnetic layer, patterning the third dielectric layer.
